(19) United States
(12) Patent Application Publication
(10) Pub. No.: US 2024/0347510 A1
(43) Pub. Date: Oct. 17, 2024

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Jeongil Lee, Suwon-si (KR); Byeongchan Kim, Suwon-si (KR); Unbyoung Kang, Suwon-si (KR); Jumyong Park, Suwon-si (KR)

(21) Appl. No.: 18/585,468

(22) Filed: Feb. 23, 2024

(30) Foreign Application Priority Data
Apr. 14, 2023 (KR) 10-2023-0049205

(51) Int. Cl. H01L 25/065; H01L 23/00; H01L 23/48; H01L 23/498

(52) U.S. Cl. CPC H01L 25/0657; H01L 23/481; H01L 23/49822; H01L 24/03; H01L 24/05; H01L 24/13; H01L 24/81; H01L 2224/03616; H01L 2224/05647; H01L 2224/13027; H01L 2224/81895; H01L 2225/06541; H01L 2924/1436

(57) ABSTRACT

A semiconductor package includes a first semiconductor chip and a second semiconductor chip stacked on the first semiconductor chip. The first semiconductor chip includes a plurality of through electrodes, first bonding pads provided on a first surface of a first substrate, a first passivation layer provided on the first surface and exposing the first bonding pads, a polishing stop layer pattern provided on a second surface of the first substrate and exposing end portions of the plurality of through electrodes, and second bonding pads provided on the polishing stop layer pattern. The second semiconductor chip includes third bonding pads provided on a first surface of a second substrate, and a second passivation layer provided on the first surface of the second substrate and exposing the third bonding pads. The first bonding pads and the third bonding pads are directly bonded to each other.

### PRIORITY STATEMENT

This application claims priority under 35 U.S.C. § 119 to Korean Patent Application No. 10-2023-0049205, filed on Apr. 14, 2023, in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a multi-chip package including a plurality of different stacked chips and a method of manufacturing the same.

### 2. Description of the Related Art

In manufacturing a three-dimensional (3D) integrated circuit (IC) package, a hybrid bonding process is performed to bond individually separated preliminary first semiconductor chips on a lower wafer on which second semiconductor chips are formed, backside surfaces of the bonded preliminary first semiconductor chips are back-lapped, a grinding process and a silicon recess process are performed to expose through electrodes (e.g., through silicon vias (TSVs)), and then, a backside surface wiring layer and bonding pads are formed on the backside surfaces of the preliminary first semiconductor chips. However, it may not be easy to control process distribution between the preliminary first semiconductor chips on the lower wafer and process distribution within each of the preliminary first semiconductor chips. For example, rounding may occur at edge regions of the preliminary first semiconductor chips in the back lap and grinding processes, and chipping may occur in which a portion of a protective layer made of silicon oxide is broken in the silicon recess process. In addition, there is a problem in that a step coverage of a polishing stop layer for a subsequent chemical mechanical polishing (CMP) process on the backside surfaces of the preliminary first semiconductor chips is deteriorated.

### SUMMARY

Example embodiments provide a semiconductor package having improved bonding quality.

Example embodiments provide a method of manufacturing the semiconductor package.

According to example embodiments, a semiconductor package includes, a first semiconductor chip including a first substrate, a plurality of through electrodes penetrating the first substrate, first bonding pads provided on a first surface of the first substrate and electrically connected to the plurality of through electrodes, a first passivation layer provided on the first surface of the first substrate and exposing at least portions of the first bonding pads, a polishing stop layer pattern provided on a second surface opposite to the first surface of the first substrate and exposing end portions of the plurality of through electrodes, and second bonding pads provided on the polishing stop layer pattern and electrically connected to the plurality of through electrodes; and a second semiconductor chip stacked on the first semiconductor chip, the second semiconductor chip including a second substrate, third bonding pads provided on a first surface of the second substrate, and a second passivation layer provided on the first surface of the second substrate and exposing at least portions of the third bonding pads. The first bonding pads and the third bonding pads are directly bonded to each other.

According to example embodiments, a semiconductor package includes, a first substrate structure including a first substrate having a first surface and a second surface opposite to the first surface, a plurality of through electrodes penetrating the first substrate and having end portions that protrude from the second surface, first bonding pads provided on the first surface of the first substrate and electrically connected to the plurality of through electrodes, a first passivation layer provided on the first surface of the first substrate and exposing at least portions of the first bonding pads, a polishing stop layer pattern provided on the second surface of the first substrate and exposing the protruding end portions of the plurality of through electrodes, and second bonding pads provided on the polishing stop layer pattern and electrically connected to the plurality of through electrodes; and a second substrate structure including a second substrate, third bonding pads provided on a first surface of the second substrate, and a second passivation layer provided on the first surface of the second substrate and exposing at least portions of the third bonding pads, wherein the second substrate structure is stacked on the first substrate structure such that the third bonding pads face the first bonding pads. The first bonding pads and the second bonding pads are directly bonded to each other. The first passivation layer and the second passivation layer are directly bonded to each other.

According to example embodiments, a semiconductor package includes a package substrate; a first semiconductor chip stacked on the package substrate; and a second semiconductor chip stacked on the first semiconductor chip. The first semiconductor chip includes a first substrate; a plurality of penetration electrodes penetrating the first substrate; first bonding pads provided on the first surface of the first substrate; a first passivation layer provided on the first surface of the first substrate and exposing the first bonding pads; a polishing stop layer pattern provided on a second surface of the first substrate opposite to the first surface and exposing end portions of the plurality of through electrodes; second bonding pads provided on the polishing stop layer pattern; and conductive bumps respectively provided on the second bonding pads. The second semiconductor chip includes a second substrate; third bonding pads provided on the first surface of the second substrate; and a second passivation layer provided on the first surface of the second substrate and exposing at least portions of the third bonding pads. The first bonding pads and the third bonding pads are directly bonded to each other.

According to example embodiments, in a method of manufacturing a semiconductor package, a first wafer including a plurality of first semiconductor chips formed therein is provided. Each of the plurality of first semiconductor chips includes a first substrate having a first surface and a second surface opposite to the first surface, a first front insulating layer provided on the first surface of the first substrate and having first bonding pads in an outer surface thereof, and a plurality of through electrodes extending from the first surface of the first substrate to a predetermined depth and having the first bonding pads. A backside surface of the first wafer is partially removed to expose end portions of the plurality of through electrodes from the second surface of the first substrate. A polishing stop layer is formed on the backside surface of the first wafer to cover the exposed end portions of the plurality of through electrodes. A first gap filling layer is formed on the polishing stop layer. The first wafer is cut to form individualized preliminary first semiconductor chips. A second wafer including a plurality of second semiconductor chips formed therein is provided. Each of the plurality of second semiconductor chips includes a second substrate having a third surface and a fourth surface opposite to the third surface, and a second front insulating layer provided on the third surface of the second substrate and having third bonding pads in an outer surface thereof. The preliminary first semiconductor chips are bonded on the second wafer to correspond to the second semiconductor chips. A second gap filling layer is formed on the second wafer to cover the preliminary first semiconductor chips. A planarization process using the polishing stop layer to detect a polishing end point is performed to form a polishing stop layer pattern that expose end portions of the through electrodes of the preliminary first semiconductor chips. Second bonding pads are formed on the polishing stop layer pattern to be electrically connected to the plurality of through electrodes.

According to example embodiments, a semiconductor package may include a first semiconductor chip and a second semiconductor chip bonded to each other. A first bonding pad of the first semiconductor chip and a third bonding pad of the second semiconductor chip may be directly bonded to each other.

The first semiconductor chip may include a first substrate, a plurality of through electrodes penetrating the first substrate, and a polishing stop layer pattern provided on a backside surface of the first substrate and exposing end portions of the plurality of through electrodes. The end portions of the plurality of through electrodes may protrude from the backside surface of the first substrate, and the polishing stop layer pattern may cover sidewalls of the end portions of the plurality of through electrodes that protrude from the backside surface of the first substrate.

Before a hybrid bonding process of the first semiconductor chip and the second semiconductor chip, a polishing stop layer may be uniformly formed over the entire backside surface of the first substrate at the wafer level to conformally cover the end portions of the protruding through electrodes. The polishing stop layer may be used to detect a polishing end point in a chemical mechanical polishing (CMP) process for exposing the end portions of the through electrodes to enable sophisticated CMP process control.

Thus, bonding quality between the first semiconductor chip and the second semiconductor chip and bonding quality between the through electrodes and a first backside insulating layer may be improved.

### BRIEF DESCRIPTION OF THE DRAWINGS

Example embodiments will be more clearly understood from the following detailed description taken in conjunction with the accompanying drawings. FIGS. 1 to 20 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIGS. 3 to 20 are views illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings. Like reference characters refer to like elements throughout.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

It will be understood that when an element is referred to as being “connected” or ‘coupled’ to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

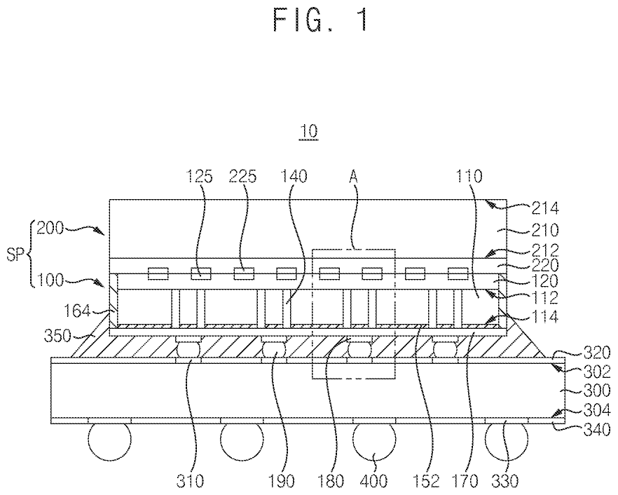

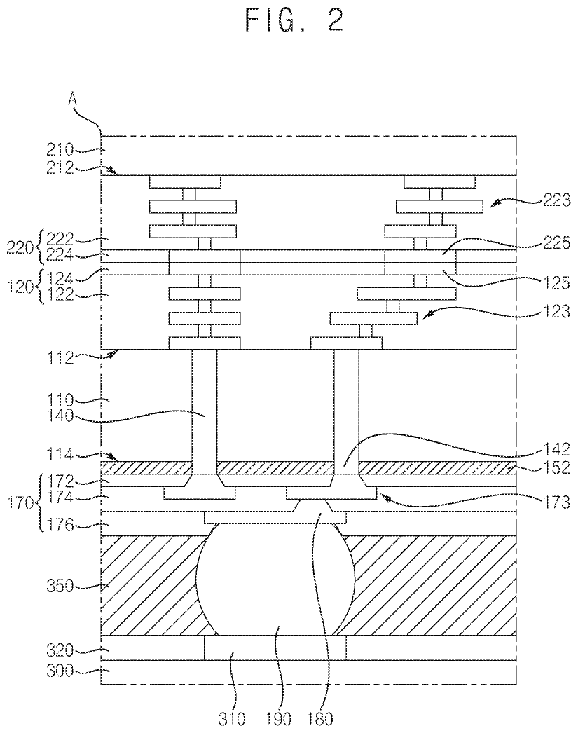

FIG. 1 is a cross-sectional view illustrating a semiconductor package in accordance with example embodiments. FIG. 2 is an enlarged cross-sectional view illustrating portion ‘A’ in FIG. 1.

Referring to FIGS. 1 to 2, a semiconductor package 10 may include a package substrate 300 and a semiconductor device SP stacked on the package substrate 300. The semiconductor device SP may include a first semiconductor chip 100 and a second semiconductor chip 200 bonded to each other. The second semiconductor chip 200 may be stacked on the first semiconductor chip 100. In addition, the semiconductor package 10 may further include external connection members 400 provided on a lower surface of the package substrate 300.

In example embodiments, the semiconductor package 10 may be a multi-chip package (MCP) including different types of semiconductor chips. The semiconductor package 10 may be a system in package (SIP) including a plurality of semiconductor chips stacked or arranged in one package to perform all or most of the functions of an electronic system.

The semiconductor package 10 may include the first semiconductor chip 100 as a first substrate structure and the second semiconductor chip 200 as a second substrate structure that are sequentially stacked on each other. One of the first semiconductor chip 100 and the second semiconductor chip 200 may be a logic chip including a logic circuit, and the other may be a memory chip or a sensor chip. The logic chip may be a controller that controls memory elements of the memory chip. For example, the logic chip may be an ASIC serving as a host such as a CPU, GPU, or SOC, or a processor chip such as an application processor (AP). The memory chip may include DRAM, SRAM, etc. The sensor chip may be a CMOS image sensor chip.

Alternatively, the semiconductor device SP may include a three-dimensional (3D) semiconductor memory device. In this case, the first and second substrate structures 100 and 200 may be bonded to each other to form a 3D semiconductor memory device such as DRAM or flash memory.

In this embodiment, the semiconductor package as a multi-chip package is illustrated as including two stacked first and second semiconductor chips 100 and 200. However, it is not limited thereto, and for example, the semiconductor package may include 4, 8, 12, or 16 stacked semiconductor chips.

In example embodiments, the first semiconductor chip 100 may include a first substrate 110, a first front insulating layer 120, a plurality of first bonding pads 125, a plurality of through electrodes 140, a polishing stop layer pattern 152, and a plurality of second bonding pads 180. In addition, the first semiconductor chip 100 may further include conductive bumps 190 as conductive connection members respectively provided on the second bonding pads 180. The conductive bumps 190 may contact the second bonding pads 180. The first semiconductor chip 100 may be mounted on the package substrate 300 via the conductive bumps 190. For example, the conductive bumps 190 may include solder bumps.

The first substrate 110 may have a first surface 112 and a second surface 114 opposite to the first surface 112. The first surface 112 may face the second semiconductor chip 200, and the second surface 114 may face the package substrate 300. The first surface 112 may be an active surface, and the second surface 114 may be an inactive surface. The active surface may be the surface on which devices are formed, and the inactive surface may be the surface which does not include any devices. Circuit patterns and cells may be formed on the first surface 112 of the first substrate 110. For example, the first substrate 110 may be a single crystal silicon substrate. The circuit patterns may include transistors, capacitors, diodes, etc. The circuit patterns may constitute circuit elements. Accordingly, the first semiconductor chip 100 may be a semiconductor device in which a plurality of circuit elements are formed.

The first front insulating layer 120 may be provided on the first surface 112 of the first substrate 110, that is, the active surface. The first front insulating layer 120 may include a plurality of insulating layers and upper wirings in the insulating layers. In addition, redistribution pads may be provided in an outermost insulating layer of the first front insulating layer 120, and the first bonding pads 125 may be provided on the redistribution pads.

For example, the first front insulating layer 120 may include a first metal wiring layer 122 and a first passivation layer 124. The first metal wiring layer 122 may include a plurality of wirings 123 therein. The first bonding pads 125 may be formed on an uppermost wiring among the plurality of wirings 123.

For example, the plurality of wirings 123 may be formed of or include aluminum (Al), copper (Cu), tin (Sn), nickel (Ni), gold (Au), platinum (Pt), or an alloy thereof. The first bonding pads 125 may include copper (Cu), aluminum (Al), nickel (Ni), cobalt (Co), tungsten (W), titanium (Ti), tin (Sn), or an alloy thereof.

The through electrode as through silicon via (TSV) 140 may be provided to vertically penetrate the first substrate 110 from the first surface 112 to the second surface 114 of the first substrate 110. In example embodiments, upper surfaces of the first substrate 110 and the through electrodes 140 may be coplanar. A first end portion of the through electrode 140 may contact the lowest wiring in the wiring layer. However, it is not limited thereto, and for example, the through electrodes 140 may penetrate the first metal wiring layer and directly contact the first bonding pads 125.

As illustrated in FIG. 2, the polishing stop layer pattern 152 may be provided on the second surface 114 of the first substrate 110, that is, a backside surface, and may expose end portions 142 of the through electrodes 140. The end portions 142 of the penetration electrodes 140 may protrude from the second surface 114 of the first substrate 110, and the polishing stop layer pattern 152 may be formed on the second surface 114 of the first substrate 110 and may cover sidewalls of the end portions 142 of the through electrodes 140 that protrude from the second surface 114 of the first substrate 110. For example, the polishing stop layer pattern 152 may contact the sidewalls of the end portions 142 of the through electrodes 140. A lower surface of the polishing stop layer pattern 152 and lower surfaces of the end portions 142 of the through electrodes 140 may be positioned on the same plane. For example, lower surfaces of the polishing stop layer pattern 152 and the through electrodes 140 may be coplanar. Accordingly, the lower surfaces of the end portions 142 of the through electrodes 140 may be exposed by the polishing stop layer pattern 152.

The polishing stop layer pattern 152 may cover the entire second surface 114 of the first substrate 110. For example, the polishing stop layer pattern 152 may contact the second surface 114 of the first substrate 110. The polishing stop layer pattern 152 may be formed of or include silicon nitride. The polishing stop layer pattern 152 may have a thickness within a range of 0.1 μm to 1 μm. Thickness may refer to the thickness or height measured in a direction perpendicular to the first surface 112 of the first substrate 110.

In example embodiments, the first semiconductor chip 100 may further include a filling layer pattern 164. The filling layer pattern 164 may cover outer surfaces of the first substrate 110 and the polishing stop layer pattern 152. The filling layer pattern 164 may contact the outer surfaces of the first substrate 110 and the polishing stop layer pattern 152. The filling layer pattern 164 may be formed of or include a material having a polishing selectivity with respect to the polishing stop layer pattern 152. The filling layer pattern 162 may be formed of or include silicon oxide.

The first backside insulating layer 170 may be provided on the polishing stop layer pattern 152 on the second surface 114 of the first substrate 110. The first backside insulating layer 170 may contact the polishing stop layer pattern 152. The second bonding pads 180 may be provided in an outer surface of the first backside insulating layer 170. The second bonding pads 180 may be disposed on the exposed surface of the through electrodes 160.

In particular, the first backside insulating layer 170 may include sequentially stacked first and second insulating layers 172 and 174 and wirings 173 in the first and second insulating layers 172 and 174. The first insulating layer 172 may be provided on the polishing stop layer pattern 152 on the second surface 114 of the first substrate 110 and may have first openings that expose the lower surfaces of the through electrodes 140. The wirings 173 may be provided on the first insulating layer 172 and may be electrically connected to the through electrodes 140 through the first openings of the first insulating layer 172. The wirings 173 may contact the through electrodes 140. The second insulating layer 174 may be provided on the first insulating layer 174 to cover the wirings 173, and may have second openings that expose at least portions of the wirings 173.

The second bonding pads 180 may be provided on the second insulating layer 174 and may be electrically connected to the wirings 173 through the second openings of the second insulating layer 174. The second bonding pads 180 may contact the wirings 173. A third insulating layer 176 serving as a passivation layer may be provided on the second insulating layer 174 to expose at least portions of the second bonding pads 180.

Accordingly, the through electrodes 140 may be electrically connected to the second bonding pads 180 through the wirings 173. Thus, the first bonding pads 125 and the second bonding pads 180 may be electrically connected to each other by the through electrodes 140.

In example embodiments, the second semiconductor chip 200 may be stacked on the first semiconductor chip 100. The second semiconductor chip 200 may include a second substrate 210, a second front insulating layer 220 and a plurality of third bonding pads 230.

The second substrate 210 may have a first surface 212 and a second surface 214 opposite to the first surface 212. The first surface 212 may be an active surface, and the second surface 214 may be an inactive surface. Circuit elements may be formed on the first surface 212 of the second substrate 210. The circuit patterns may include transistors, capacitors, diodes, etc. The circuit patterns may constitute circuit elements. Accordingly, the second semiconductor chip 200 may be a semiconductor device in which a plurality of circuit elements are formed.

The second front insulating layer 220 may be provided on the first surface 212 of the second substrate 210, that is, the active surface. The second front insulating layer 220 may include a plurality of insulating layers and upper wirings in the insulating layers. In addition, redistribution pads may be provided in an outermost insulating layer of the second front insulating layer 220, and the third bonding pads 225 may be provided on the redistribution pads.

For example, the second front insulating layer 220 may include a second metal wiring layer 222 and a second passivation layer 224. The second metal wiring layer 222 may include a plurality of wirings 223 therein. The third bonding pads 225 may be formed on an uppermost wiring among the plurality of wirings 223.

As illustrated in FIG. 2, the first semiconductor chip 100 and the second semiconductor chip 200 may be bonded to each other to provide the stacked package SP. The first surface 212 of the second substrate 210 may face the first surface 112 of the first substrate 110. The second front insulating layer 220 and the first front insulating layer 120 may be directly bonded to each other. Accordingly, the first bonding pads 125 and the third bonding pads 225 between the first semiconductor chip 100 and the second semiconductor chip 200 may be bonded to each other by Cu—Cu hybrid bonding (pad to pad direct bonding).

The first passivation layer 124 of the first semiconductor chip 100 and the second passivation layer 224 of the second semiconductor chip 200 may be directly bonded to each other. The first passivation layer 124 and the second passivation layer 224 may make contact with each other to provide a bonding structure by including an insulating material providing excellent bonding strength. The first passivation layer 124 and the second passivation layer 224 may be bonded to each other by a high-temperature annealing process while in contact with each other. At this time, the bonding structure may have a relatively stronger bonding strength by covalent bonding.

In example embodiments, the stacked package SP including the first semiconductor chip 100 and the second semiconductor chip 200 bonded to each other may be mounted on the package substrate 300. The stack package SP may be mounted on the package substrate 300 via the conductive bumps 190 formed on the second bonding pads 180 of the first semiconductor chip 100.

The package substrate 300 may be a substrate having an upper surface 302 and a lower surface 304 opposite to the upper surface 302. For example, the package substrate 300 may be a printed circuit board (PCB). The printed circuit board may be a multilayer circuit board having vias and various circuits therein.

The second surface 114 of the first substrate 110 of the first semiconductor chip 100 may face the package substrate 300. The conductive bumps 190 of the first semiconductor chip 100 may be bonded to substrate pads 310 on the upper surface 302 of the package substrate 300. For example, the conductive bumps 190 may contact the substrate pads 310.

An underfill member 350 may be interposed between the first semiconductor chip 100 and the package substrate 300. The underfill member 350 may contact the lower and side surfaces of the first backside insulating layer 170, a portion of the sides surface of the filling layer pattern 164, side surfaces of the conductive bumps 190, and an upper surface of an insulating layer 320. For example, the underfill member 350 may be formed of or include an epoxy material to reinforce a gap between the first semiconductor chip 100 and the package substrate 300.

External connection pads 330 may be provided on the lower surface 304 of the package substrate 300, and external connection members 400 may be respectively disposed on the external connection pads 330. Upper surfaces of the external connection pads 330 may be coplanar with an upper surface of the insulating layer 340, and lower surfaces of the external connection pads 330 may be coplanar with a lower surface of the insulating layer 340. The insulating layer 340 may be provided on the lower surface 304 of the package substrate 300, and may contact side surfaces of the external connection pads 330. For example, the external connection member 400 may be a solder ball. The semiconductor package 10 may be mounted on a module substrate (not illustrated) via the solder balls to form a memory module.

As mentioned above, the semiconductor package 10 may include the package substrate 300 and the stack package SP stacked on the package substrate 300 and including the first semiconductor chip 100 and the second semiconductor chip 200 bonded to each other. The first bonding pads 125 of the first semiconductor chip 100 and the third bonding pads 225 of the second semiconductor chip 200 may be directly bonded to each other.

The first semiconductor chip 100 may include the polishing stop layer pattern 152 that is provided on the backside surface 114 of the first substrate 110 and exposes the end portions 142 of the plurality of through electrodes 140. The end portions 142 of the plurality of through electrodes 140 may protrude from the backside surface 114 of the first substrate 110, and the polishing stop layer pattern 152 may cover the sidewalls of the end portions 142 of the plurality of through electrodes 140 that protrude from the backside surface 114 of the first substrate 110.

Before the hybrid bonding process of the first semiconductor chip 100 and the second semiconductor chip 200, a polishing stop layer may be uniformly formed over the entire backside surface 114 of the first substrate 110 at the wafer level to conformally cover the end portions 142 of the protruding through electrodes 140. The polishing stop layer may be used to detect a polishing end point in a chemical mechanical polishing (CMP) process for exposing the end portions 142 of the through electrodes 140 to enable sophisticated CMP process control.

Thus, bonding quality between the first semiconductor chip 100 and the second semiconductor chip 200 and bonding quality between the through electrodes 140 and the first backside insulating layer 170 may be improved.

Hereinafter, a method of manufacturing the semiconductor package of FIG. 1 will be described.

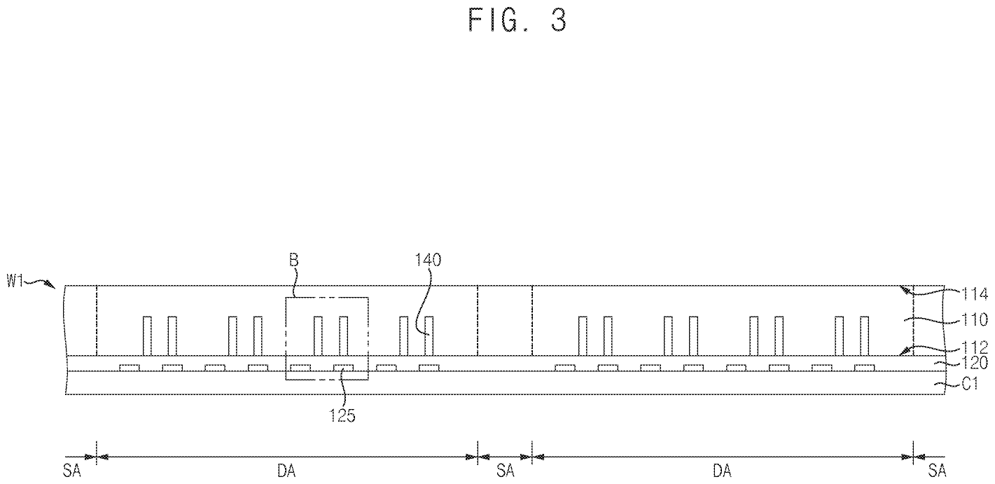

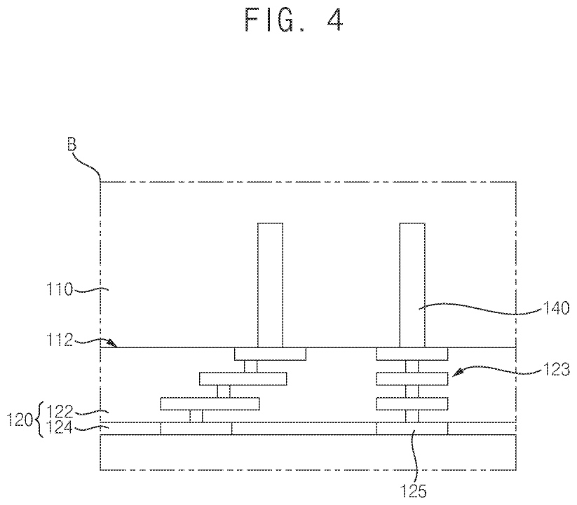

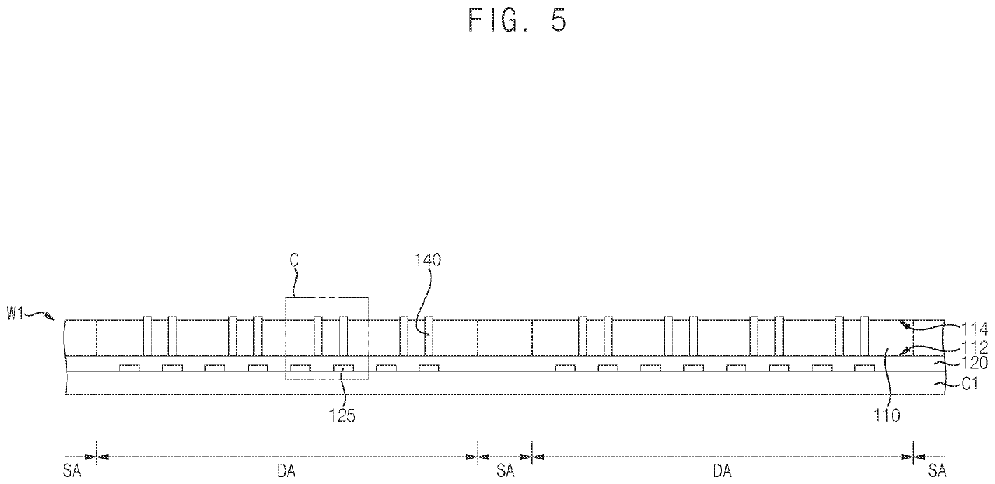

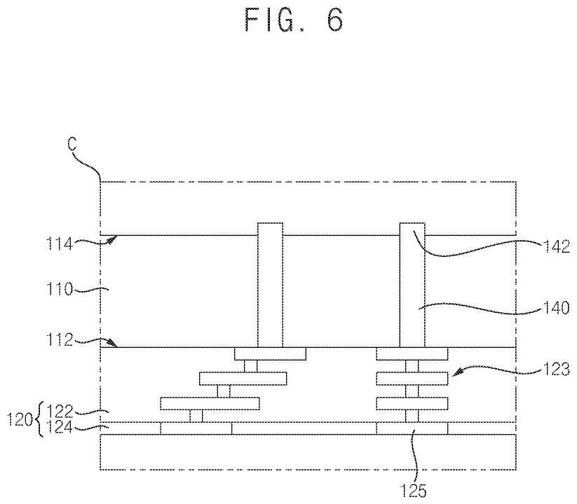

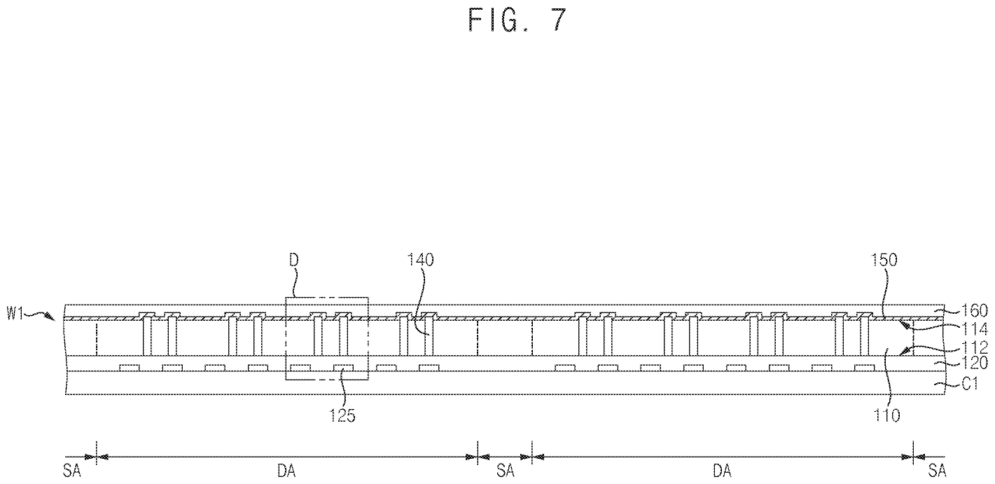

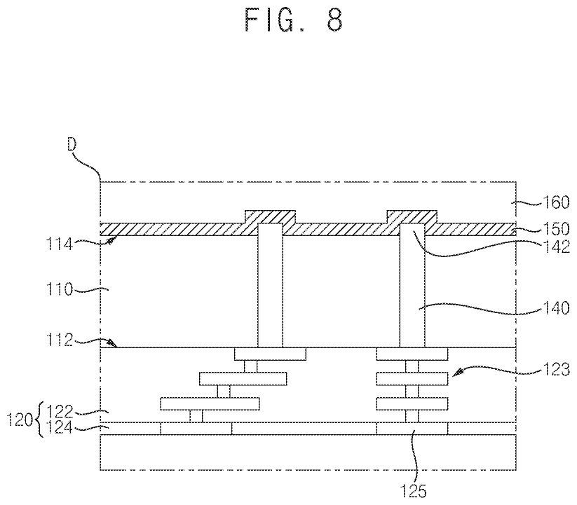

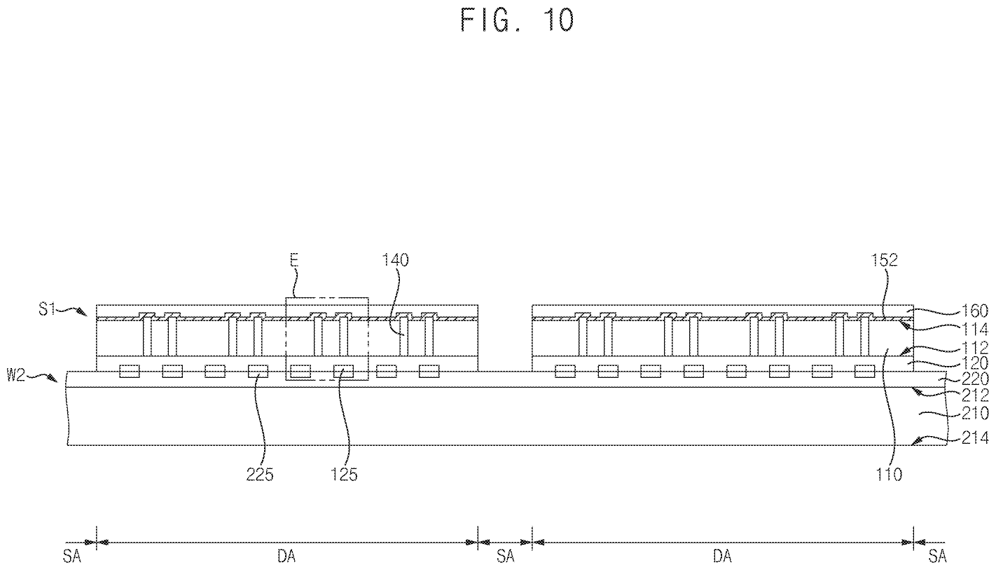

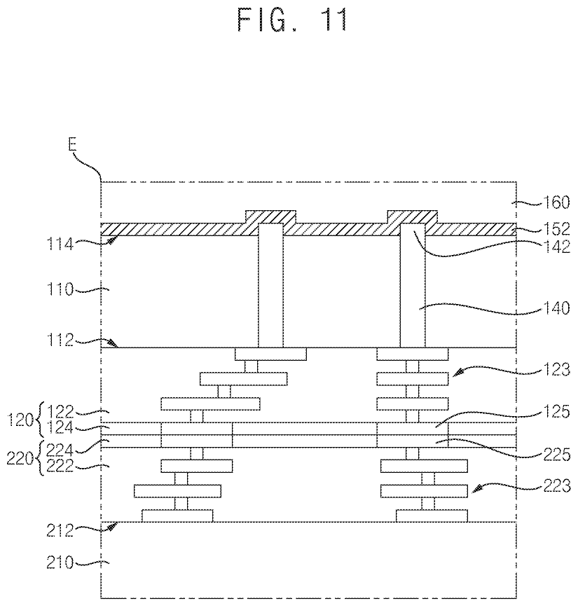

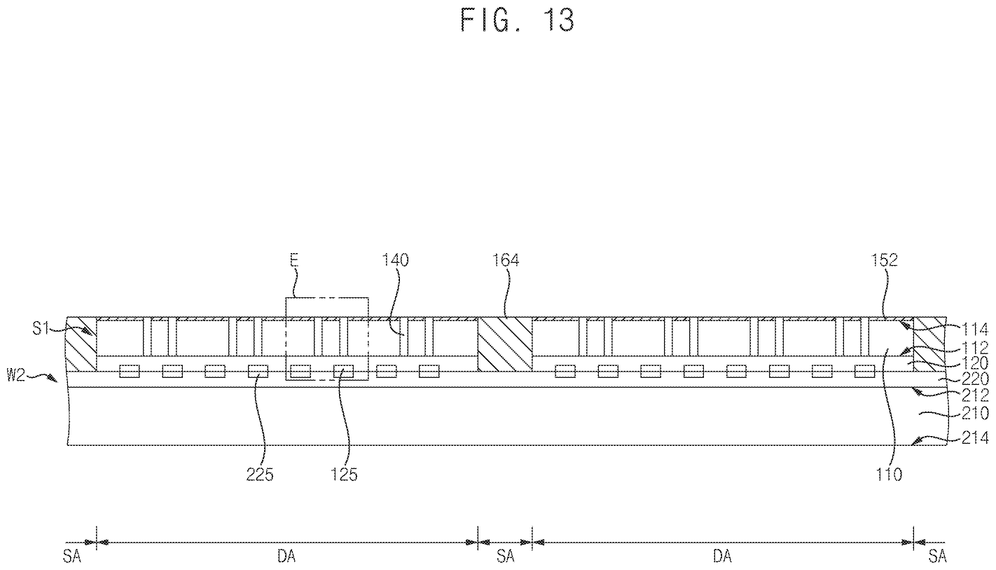

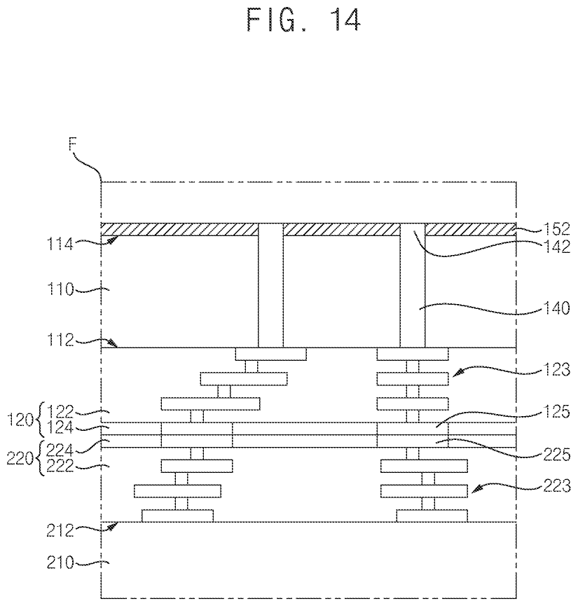

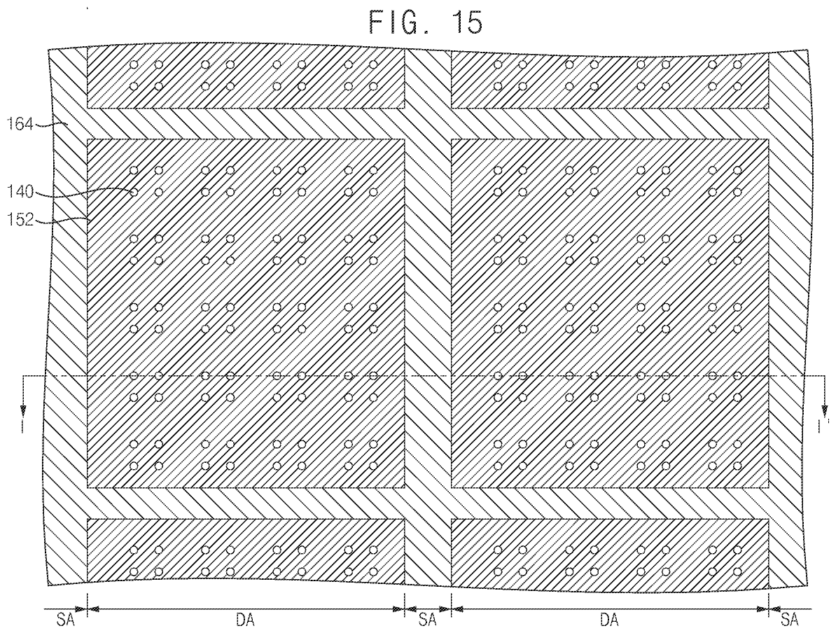

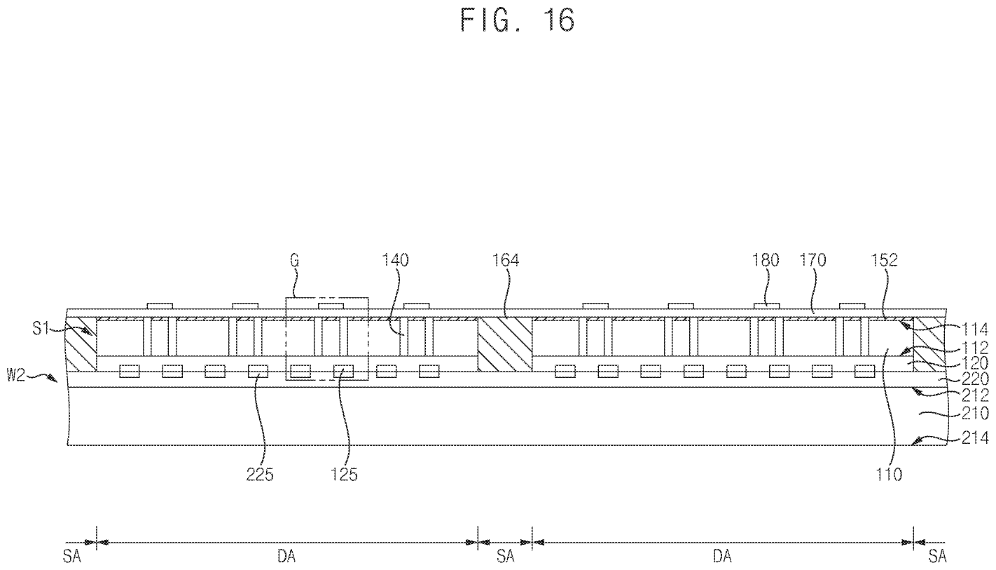

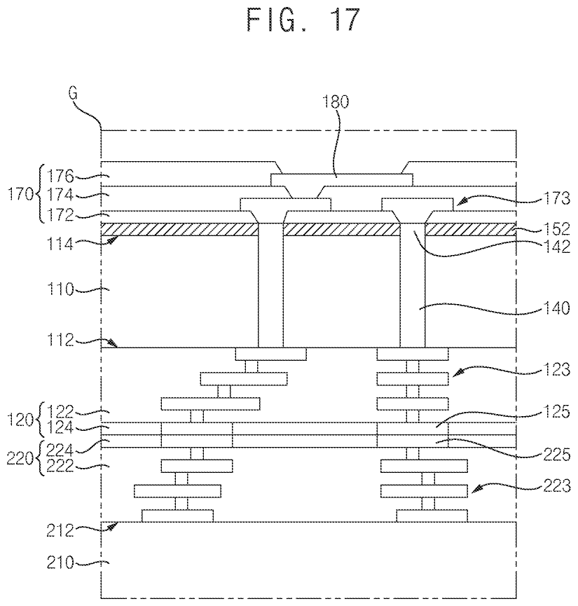

FIGS. 3 to 15 are views illustrating a method of manufacturing a semiconductor package in accordance with example embodiments. FIGS. 3 to 14 and FIGS. 16 to 20 are cross-sectional views illustrating a method of manufacturing a semiconductor package in accordance with example embodiments. FIG. 4 is an enlarged cross-sectional view illustrating portion ‘B’ in FIG. 3. FIG. 6 is an enlarged cross-sectional view illustrating portion ‘C’ in FIG. 5. FIG. 8 is an enlarged cross-sectional view illustrating portion ‘D’ in FIG. 7. FIG. 11 is an enlarged cross-sectional view illustrating portion ‘E’ in FIG. 10. FIG. 14 is an enlarged cross-sectional view illustrating portion ‘F’ in FIG. 13. FIG. 15 is a plan view of FIG. 13. FIG. 13 is a cross-sectional view taken along the line I-I′ in FIG. 15. FIG. 17 is an enlarged cross-sectional view illustrating portion ‘G’ in FIG. 16.

Referring to FIGS. 3 and 4, first, a first wafer W1 including a plurality of first semiconductor chips (first substrate structures) formed therein may be prepared.

In example embodiments, the first wafer W1 may include a first substrate 110 and a first front insulating layer 120 having first bonding pads 125 provided in an outer surface thereof. Additionally, the first wafer W1 may include a plurality of through electrodes 140 that are provided in the first substrate 110 and are electrically connected to the first bonding pads 125.

The first substrate 110 may have a first surface 112 and a second surface 114 opposite to the first surface 112. The first substrate 110 may include a die regions DA where circuit patterns are formed and a scribe lane region SA surrounding the die regions DA. The first substrate 110 may be individualized by being cut along the scribe lane region SA that divides the plurality of die regions DA of the first wafer W1 by a following dicing process (singulation process).

For example, the first substrate 110 may be formed of or include silicon, germanium, silicon-germanium, or III-V compounds, e.g., GaP, GaAs, GaSb, etc. In some embodiments, the second substrate 210 may be a silicon-on-insulator (SOI) substrate, or a germanium-on-insulator (GOI) substrate. Memory cells and peripheral circuits for driving the memory cells may be formed in the die region DA. Alternatively, logic elements may be formed in the die region DA.

The circuit patterns may include transistors, capacitors, diodes, etc. The circuit patterns may constitute circuit elements. Accordingly, the first semiconductor chip may be a semiconductor device in which a plurality of circuit elements are formed. The circuit patterns may be formed by performing a Fab process called a Front End of Line (FEOL) process for manufacturing semiconductor devices on the first surface 112 of the first substrate 110. A surface of the first substrate on which the FEOL process is performed may be referred to as a front surface of the first substrate, and a surface opposite to the front surface may be referred to as a backside surface. For example, the first substrate 110 may have a thickness in a range of about 50 μm to about 1,000 μm.

The circuit element may include a plurality of memory devices. Examples of the memory device include a volatile semiconductor memory device and a non-volatile semiconductor memory device. Examples of the volatile semiconductor memory device include DRAM, SRAM, etc. Examples of the non-volatile semiconductor memory device include EPROM, EEPROM, Flash EEPROM, etc.

The first front insulating layer 120 may be formed on the first surface 112 of the first substrate 110, that is, the front surface. The first front insulating layer 120 may include a plurality of insulating layers 122 and 124 and wirings 123 in the insulating layers. In addition, the first bonding pads 125 may be provided in an outermost insulating layer of the first front insulating layer 130.

As illustrated in FIG. 4, the first front insulating layer 120 may include a first metal wiring layer 122 and a first passivation layer 124.

The first metal wiring layer 122 may include a plurality of wirings 123 therein. For example, the first metal wiring layer 122 may include a metal wiring structure having the plurality of wirings 123 vertically stacked in buffer layers and insulating layers. The first bonding pads 125 may be formed on an uppermost wiring among the plurality of wirings 123. For example, the wirings may be formed of or include aluminum (Al), copper (Cu), tin (Sn), nickel (Ni), gold (Au), platinum (Pt), or an alloy thereof.

The first passivation layer 124 may be formed on the first metal wiring layer 122 and may expose at least a portion of the first bonding pads 125. The first passivation layer 124 may include a plurality of stacked insulating layers. For example, the first passivation layer 124 may include an organic passivation layer and an inorganic passivation layer sequentially stacked on each other. The first passivation layer may include an oxide layer, silicon nitride or silicon carbonitride.

Although not illustrated in the figures, an insulation interlayer may be provided on the first surface 112 of the first substrate 110 to cover the circuit patterns. The insulation interlayer may be formed of, for example, silicon oxide or a low dielectric material. The insulation interlayer may include lower wirings therein that are electrically connected to the circuit patterns. Accordingly, the circuit pattern may be electrically connected to the first bonding pads 125 by the lower wirings and the wirings.

A plurality of through electrodes 140 such as through silicon vias (TSVs) may vertically penetrate the insulation interlayer and may extend from the first surface 112 of the first substrate 110 to a predetermined depth. The through electrodes 140 may contact a lowest wiring of the metal wiring structure. Accordingly, the through electrodes 140 may be electrically connected to the first bonding pads 125 through the wirings 123.

A liner layer (not illustrated) may be provided on an outer surface of the through electrode 140. The liner layer may include silicon oxide or carbon-doped silicon oxide. The liner layer may electrically insulate the through electrode 140 from the first substrate 110 and the first metal wiring layer 122.

The through electrodes 140 and the first bonding pads 125 may be formed of or include the same metal. For example, the metal may be formed of or include copper (Cu). However, it may not be limited thereto, and may be formed of or include a material (e.g., gold (Au)) that can be combined by interdiffusion of metals by a high-temperature annealing process.

Referring to FIGS. 5 and 6, the second surface 114 of the first substrate 110 may be partially removed to exposed an end portion 142 of the through electrode 140.

In example embodiments, the second surface 114 of the first substrate 110 may be partially removed using a wafer support system (WSS). After attaching the first wafer W1 on a carrier substrate C1 by using an adhesive film, the second surface 114 of the first substrate 110 may be partially removed until the portion of the through electrode 140 is exposed.

In particular, first, a grinding process such as a back lap process may be performed to partially remove the second surface 114 of the first substrate 110, and then an etching process such as a silicon recess process may be performed to expose the end portion 142. Accordingly, a thickness of the first substrate 110 may be reduced to a desired thickness. For example, the thickness of the first substrate 110 may be in a range of from about 10 μm to about 50 μm.

In the back lap process, the entire backside surface of the first wafer W1 may be ground. The silicon recess process may selectively etch only silicon in the backside surface of the first wafer W1. The etching process may be an isotropic dry etching process. The etching process may include a plasma etching process. The plasma etching process may be performed using inductively coupled plasma, capacitively coupled plasma, microwave plasma, etc.

Since the grinding process and the etching process are performed in the wafer level, the entire second surface 114 of the first substrate 110 may be reduced to a uniform thickness. Thus, the end portions 142 of the through electrodes 140 have the same heights from the second surface 114 of the first substrate 110 over the entire second surface 114 of the first substrate 110.

Referring to FIGS. 7 and 8, a polishing stop layer 150 may be formed on the second surface 114 of the first substrate 110, and a first gap filling layer 160 may be formed on the polishing stop layer 150.

In example embodiments, the polishing stop layer 150 may be formed conformally to cover the end portions 142 of the through electrodes 140 that protrude from the second surface 114 of the first substrate 110. The polishing stop layer 150 may cover the entire second surface 114 of the first substrate 110. For example, the polishing stop layer 150 may have a thickness within a range of 0.1 μm to 1 μm. The polishing stop layer 150 may include a material that can be used to detect a polishing end point in a following chemical mechanical polishing process. The polishing stop layer 150 may include a silicon nitride layer. The thickness and material of the polishing stop layer may be selected in consideration of a polishing selectivity ratio in the following chemical mechanical polishing process, polishing conditions, etc.

The first gap filling layer 160 may be formed on the polishing stop layer 150 to fill a gap between the protruding end portions 142 of the through electrodes 140. The first gap filling layer 160 may include silicon oxide such as TEOS. The first gap filling layer 160 may have a thickness within a range of 5 μm to 20 μm.

The first gap filling layer 160 may be formed on the second surface 114 of the first substrate 110 to prevent warping of the relatively thin first substrate 110 and to prevent defects such as peeling, chipping, etc. at an edge region in a subsequent sawing process.

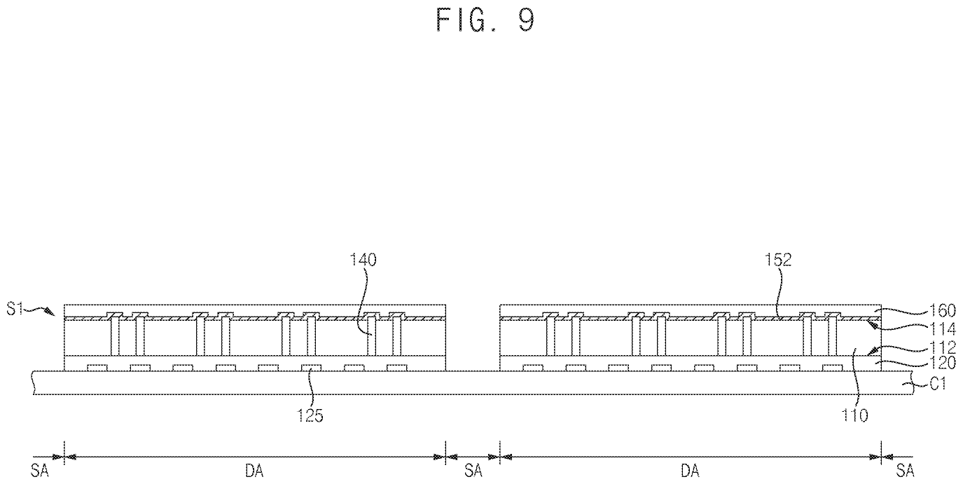

Referring to FIG. 9, the first wafer W1 may be cut along the scribe lane region SA to form an individualized preliminary first semiconductor chip (preliminary first substrate structure) S1. The first wafer W1 may be cut by a sawing process. The preliminary first semiconductor chip S1 may have a size corresponding to the die region DA.

Referring to FIGS. 10 and 11, a plurality of preliminary first semiconductor chips S1 may be respectively attached on a second wafer W2 (die-to-wafer hybrid bonding process).

In example embodiments, after a second wafer W2 including a plurality of second semiconductor chips (second substrate structures) formed therein is prepared, the preliminary first semiconductor chips S1 may be bonded on the second wafer W2 corresponding to die regions DA, respectively. The preliminary first semiconductor chips S1 may be spaced apart from each other on the second wafer W2. Each of the preliminary first semiconductor chips S1 may be stacked such that the first surface 112 of the first substrate 110 of the preliminary first semiconductor chip S1 faces the second wafer W2.

For example, a die bonding apparatus may pick up the individualized preliminary first semiconductor chip S1 and bond it to the second wafer W2. The die bonding apparatus may attach the preliminary first semiconductor chip S1 onto the second wafer W2 by performing a thermal compression process at a predetermined temperature (e.g., about 400° C. or less). By the thermal compression process, the preliminary first semiconductor chip S1 and the second wafer W2 may be bonded to each other through hybrid bonding. That is, a front surface of the preliminary first semiconductor chip S1, that is, the first front insulating layer 120 on the first surface 112 of the first substrate 110 may be directly bonded with a second front insulating layer 220 on a second substrate 210 of the second wafer W2.

In example embodiments, the second wafer W2 may include a second substrate 210 and the second front insulating layer 220 having third bonding pads 225 that are formed in an outer surface thereof. The second substrate 210 may have a first surface 212 and a second surface 214 opposite to the first surface 212. The second substrate 210 may include die regions DA and a scribe lane region SA surrounding the die regions DA. The second substrate 210 may be individualized into semiconductor chips by being cut along the scribe lane region SA that divides the plurality of die regions DA of the second wafer W2 by a following dicing process (singulation process).

Circuit elements may be formed in the die regions DA on the first surface 212 of the second substrate 210. The second semiconductor chip may be a logic chip including a logic circuit. The logic chip may be a controller that controls memory elements of the first semiconductor chip. The second semiconductor chip may be a processor chip such as an ASIC, an application processor (AP), etc. serving as a host such as a CPU, GPU, or SOC.

The second front insulating layer 220 may be formed on the first surface 212 of the second substrate 210, that is, the front surface. The second front insulating layer 220 may include a plurality of insulating layers 222 and 224 and wirings 223 in the insulating layers. In addition, the third bonding pads 225 may be provided in an outermost insulating layer of the second front insulating layer 230.

As illustrated in FIG. 11, the second front insulating layer 220 may include a second metal wiring layer 222 and a second passivation layer 224.

The second metal wiring layer 222 may include a plurality of wirings 223 therein. For example, the second metal wiring layer 222 may include a metal wiring structure having the plurality of wirings 223 vertically stacked in buffer layers and insulating layers. The third bonding pads 225 may be formed on an uppermost wiring among the plurality of wirings 223. For example, the wirings may be formed of or include aluminum (Al), copper (Cu), tin (Sn), nickel (Ni), gold (Au), platinum (Pt), or an alloy thereof.

The second passivation layer 224 may be formed on the second metal wiring layer 222 and may expose at least a portion of the third bonding pads 225. The second passivation layer 224 may include a plurality of stacked insulating layers. For example, the second passivation layer 224 may include an organic passivation layer and an inorganic passivation layer sequentially stacked on each other. The first passivation layer may include an oxide layer, silicon nitride or silicon carbonitride.

Although not illustrated in the figures, an insulation interlayer may be provided on the second surface 212 of the second substrate 210 to cover circuit patterns formed on the first surface 212 of the second substrate 210. The insulation interlayer may be formed of, for example, silicon oxide or a low dielectric material. The insulation interlayer may include lower wirings therein that are electrically connected to the circuit patterns. Accordingly, the circuit pattern may be electrically connected to the third bonding pads 225 by the lower wirings and the wirings.

The first bonding pads 125 of the preliminary first semiconductor chip S1 and the third bonding pads 225 of the second wafer W2 may be directly bonded to each other. When the preliminary first semiconductor chip S1 and the second wafer W2 are bonded to each other by die-to-wafer bonding, the first bonding pads 125 of the preliminary first semiconductor chip S1 and the third bonding pads 225 of the second wafer W2 may be bonded to each other by Cu—Cu hybrid bonding.

The first passivation layer 124 of the preliminary first semiconductor chip S1 and the second passivation layer 224 of the second wafer W2 may be directly bonded to each other. The first passivation layer 124 and the second passivation layer 224 may make contact with each other to provide a bonding structure that includes an insulating material providing excellent bonding strength. The first passivation layer 124 and the second passivation layer 224 may be bonded to each other by a high-temperature annealing process while in contact with each other. At this time, the bonding structure may have a relatively stronger bonding strength by covalent bonding.

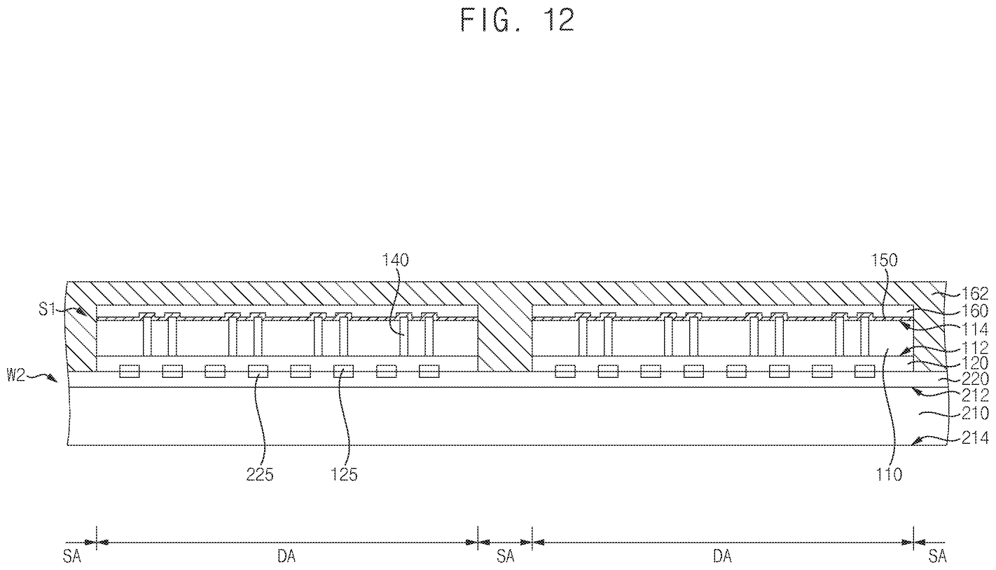

Referring to FIG. 12, a second gap filling layer 162 may be formed on the second wafer W2 to cover the preliminary first semiconductor chips S1. A portion of the second gap filling layer 162 may be formed to fill a space between the preliminary first semiconductor chips S1 that are spaced apart from each other on the second wafer W2. The second gap fill layer 162 may cover upper surfaces and outer surfaces of the preliminary first semiconductor chips S1.

For example, the second gap fill layer 162 may include a material having a polishing selectivity with respect to the polishing stop layer 150. The second gap fill filling layer 162 may include the same material as the first gap filling layer 160. The second gap fill layer 162 may include silicon oxide. The second gap filling layer 162 may have a thickness within a range of 10 μm to 60 μm.

Referring to FIGS. 13 to 15, a planarization process may be performed to expose end portions 142 of the through electrodes 140 of preliminary first semiconductor chips S1.

In example embodiments, the second gap filling layer 162 and the first gap filling layer 160 may be partially removed by performing a chemical mechanical polishing (CMP) process in which the polishing stop layer 150 is used to detect a polishing endpoint, to expose the end portions 142 of the through electrodes 140. The end portions 142 of the through electrodes 140 and portions of the polishing stop layer 150 covering them may be removed by the CMP process to form a polishing stop layer pattern 152 on the second surface 114 of the first substrate 110.

The polishing stop layer pattern 152 may expose end portions of the through electrodes 140. The end portions of the through electrodes 140 may protrude from the second surface 114 of the first substrate 110, and the polishing stop layer pattern 152 may cover sidewalls of the end portions of the through electrodes 140 that protrude from the second surface 114 of the first substrate 110. Accordingly, upper surfaces of the through electrodes 140 may be exposed by the polishing stop layer pattern 152. An upper surface of the polishing stop layer pattern 152 and the exposed upper surfaces of the through electrodes 140 may be positioned on the same plane.

In this case, a portion of the second gap filling layer 162 filling the space between the preliminary first semiconductor chips S1 that are spaced apart from each other may not be removed and may remain as a filling layer pattern 164. The filling layer pattern 164 may cover outer surfaces of the preliminary first semiconductor chips S1. The filling layer pattern 164 may cover an outer surface of the first substrate 110 and an outer surface of the polishing stop layer pattern 152.

Before the hybrid bonding process of the preliminary first semiconductor chips S1 and the second wafer W2, the polishing stop layer 150 may be uniformly formed over the entire second surface 114 of the first substrate 110 at the wafer level to conformally cover the end portions 142 of the protruding through electrodes 140. The polishing stop layer 150 may be used to detect a polishing endpoint in the chemical mechanical polishing (CMP) process to enable sophisticated CMP process control.

Referring to FIGS. 16 and 17, a first backside insulating layer 170 having second bonding pads 180 may be formed. The second bonding pads 180 may be formed on an outer surface of the polishing stop layer pattern 152 on the second surface 114 of the first substrate 110.

As illustrated in FIG. 17, a first insulating layer 172 having first openings that expose the upper surfaces of the through electrodes 140 may be formed on the polishing stop layer pattern 152 on the second surface 114 of the first substrate 110, and wirings 173 may be formed on the first insulating layer 172 to be electrically connected to the through electrodes 140 through the first openings. A second insulating layer 174 having second openings that expose at least portions of the wirings 173 may be formed on the first insulating layer 172, and second bonding pads 180 may be formed on the second insulating layer 174 to be electrically connected to the wirings 173 through the second openings. A third insulating layer 176 as a passivation layer may be formed on the second insulating layer 174 to expose at least portions of the second bonding pads 180.

Thus, the through electrodes 140 may be electrically connected to the second bonding pads 180 through the wirings 173.

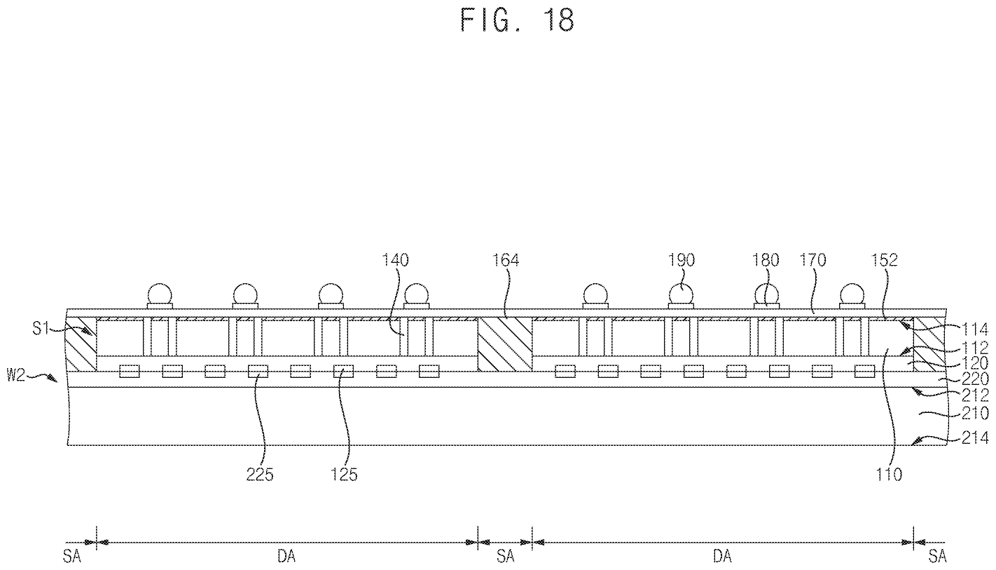

Referring to FIG. 18, conductive bumps 190 may be formed on the second bonding pads 180, respectively.

For example, a seed layer and a photoresist layer may be formed on the third insulating layer 176, an exposure process may be performed to form a photoresist pattern having openings that expose bump regions, and the openings of the photoresist pattern may be filled with a conductive material, the photoresist pattern may be removed, and a reflow process may be performed to form conductive bumps 190. Alternatively, the conductive bumps may be formed by a screen printing method, a deposition method, or the like.

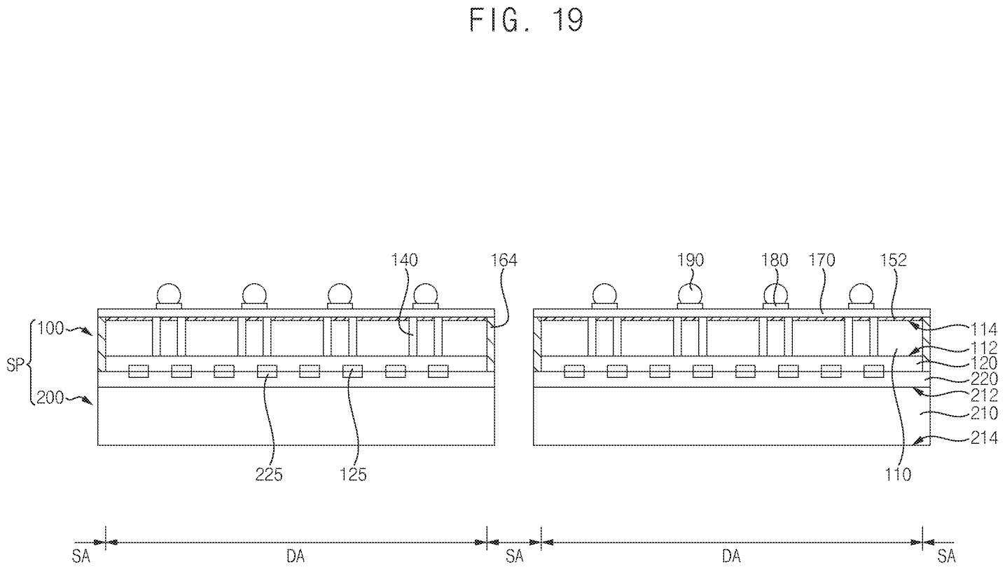

Referring to FIG. 19, the second wafer W2 may be cut along the scribe lane region SA to form a stacked package SP as an individual semiconductor device including a first semiconductor chip 100 and a second semiconductor chip 200 bonded to each other.

As at least a portion of the scribe lane region SA of the second wafer W2 is removed, the filling layer pattern 164 may be formed to cover the outer surfaces of the first substrate 110 and the polishing stop layer pattern 152.

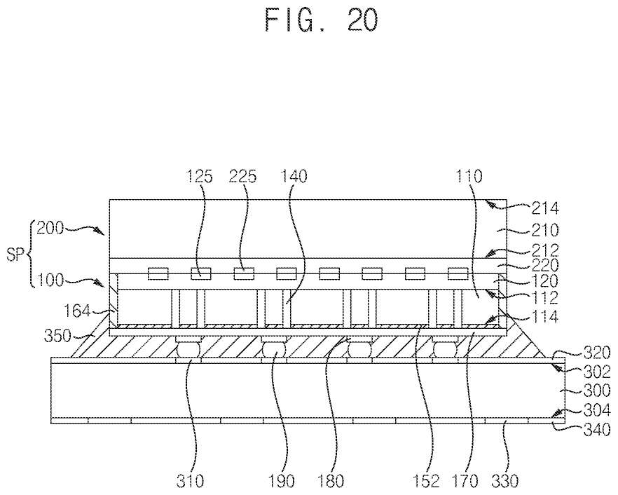

Referring to FIG. 20, the stack package SP may be mounted on a package substrate 300.

In example embodiments, the first semiconductor chip 100 may be mounted on the package substrate 300 via the conductive bumps 190. The second surface 114 of the first substrate 110 of the first semiconductor chip 100 may face the package substrate 300. The conductive bumps 190 of the first semiconductor chip 100 may be bonded to substrate pads 310 on an upper surface 302 of the package substrate 300. Upper surfaces of the substrate pads 310 may be coplanar with an upper surface of the insulating layer 320, and lower surfaces of the substrate pads 310 may be coplanar with a lower surface of the insulating layer 320. The insulating layer 320 may contact side surfaces of the substrate pads 310.

Then, an underfill member 350 may be underfilled between the first semiconductor chip 100 and the package substrate 300. While moving a dispenser nozzle along a side of the first semiconductor chip 100, an underfill solution may be dispensed between the first semiconductor chip 100 and the package substrate 300, and the underfill solution may be cured to form an underfill member 350.

For example, the underfill member may include an epoxy material to reinforce a gap between the first semiconductor chip 100 and the package substrate 300.

Then, external connection members 400 (see FIG. 1) may be disposed on external connection pads 330 on a lower surface 304 of the package substrate 300 to complete a semiconductor package 10 (see FIG. 1).

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a first semiconductor chip including a first substrate, a plurality of through electrodes penetrating the first substrate, first bonding pads provided on a first surface of the first substrate and electrically connected to the plurality of through electrodes, a first passivation layer provided on the first surface of the first substrate and exposing at least portions of the first bonding pads, a polishing stop layer pattern provided on a second surface opposite to the first surface of the first substrate and exposing end portions of the plurality of through electrodes, and second bonding pads provided on the polishing stop layer pattern and electrically connected to the plurality of through electrodes; and
a second semiconductor chip stacked on the first semiconductor chip, the second semiconductor chip including a second substrate, third bonding pads provided on a first surface of the second substrate, and a second passivation layer provided on the first surface of the second substrate and exposing at least portions of the third bonding pads,
wherein the first bonding pads and the third bonding pads are directly bonded to each other.

2. The semiconductor package of claim 1, wherein the first passivation layer and the second passivation layer are directly bonded to each other.

3. The semiconductor package of claim 1, wherein the end portions of the plurality of through electrodes protrude from the second surface of the first substrate, and the polishing stop layer pattern covers side walls of the end portions of the plurality of through electrodes that protrude from the second surface of the first substrate.

4. The semiconductor package of claim 1, wherein a lower surface of the polishing stop layer pattern and lower surfaces of the end portions of the plurality of through electrodes are positioned on a same plane.

5. The semiconductor package of claim 1, wherein the polishing stop layer pattern includes silicon nitride.

6. The semiconductor package of claim 1, wherein the polishing stop layer pattern has a thickness within a range of 0.1 μm to 1 μm.

7. The semiconductor package of claim 1, wherein the polishing stop layer pattern covers the entire second surface of the first substrate.

8. The semiconductor package of claim 1, wherein the first semiconductor chip further comprises a filling layer pattern that covers outer surfaces of the first substrate and the polishing stop layer pattern.

9. The semiconductor package of claim 8, wherein the filling layer pattern includes silicon oxide.

10. The semiconductor package of claim 1, wherein the first semiconductor chip further comprises conductive bumps that are respectively provided on the second bonding pads.

11. A semiconductor package, comprising:
a first substrate structure including a first substrate having a first surface and a second surface opposite to the first surface, a plurality of through electrodes penetrating the first substrate and having end portions that protrude from the second surface, first bonding pads provided on the first surface of the first substrate and electrically connected to the plurality of through electrodes, a first passivation layer provided on the first surface of the first substrate and exposing at least portions of the first bonding pads, a polishing stop layer pattern provided on the second surface of the first substrate and exposing the protruding end portions of the plurality of through electrodes, and second bonding pads provided on the polishing stop layer pattern and electrically connected to the plurality of through electrodes; and
a second substrate structure including a second substrate, third bonding pads provided on a first surface of the second substrate, and a second passivation layer provided on the first surface of the second substrate and exposing at least portions of the third bonding pads, wherein the second substrate structure is stacked on the first substrate structure such that the third bonding pads face the first bonding pads,
wherein the first bonding pads and the second bonding pads are directly bonded to each other, and
wherein the first passivation layer and the second passivation layer are directly bonded to each other.

12. The semiconductor device of claim 11, wherein the polishing stop layer pattern covers sidewalls of the protruding end portions of the plurality of through electrodes.

13. The semiconductor device of claim 11, wherein a lower surface of the polishing stop layer pattern and lower surfaces of the protruding end portions of the plurality of through electrodes are positioned on a same plane.

14. The semiconductor device of claim 11, wherein the polishing stop layer pattern includes silicon nitride.

15. The semiconductor device of claim 11, wherein the polishing stop layer pattern has a thickness within a range of 0.1 μm to 1 μm.

16. The semiconductor device of claim 11, wherein the polishing stop layer pattern covers the entire second surface of the first substrate.

17. The semiconductor device of claim 11, wherein the first substrate structure further comprises a filling layer pattern covering outer surfaces of the first substrate and the polishing stop layer pattern.

18. The semiconductor device of claim 11, wherein the filling layer pattern includes silicon oxide.

19. The semiconductor device of claim 11, wherein the first substrate structure further includes conductive bumps that are respectively provided on the second bonding pads.

20. A semiconductor package, comprising:
a package substrate;
a first semiconductor chip stacked on the package substrate; and
a second semiconductor chip stacked on the first semiconductor chip,
wherein the first semiconductor chip includes:
a first substrate;
a plurality of penetration electrodes penetrating the first substrate;
first bonding pads provided on the first surface of the first substrate;
a first passivation layer provided on the first surface of the first substrate and exposing the first bonding pads;
a polishing stop layer pattern provided on a second surface of the first substrate opposite to the first surface and exposing end portions of the plurality of through electrodes;
second bonding pads provided on the polishing stop layer pattern; and
conductive bumps respectively provided on the second bonding pads,
wherein the second semiconductor chip includes:
a second substrate;
third bonding pads provided on the first surface of the second substrate; and
a second passivation layer provided on the first surface of the second substrate and exposing at least portions of the third bonding pads, and
wherein the first bonding pads and the third bonding pads are directly bonded to each other.
